(19) United States
(12) Patent Application Publication
(10) Pub. No.: US 2013/0023118 A1
(43) Pub. Date: Jan. 24, 2013

(54) METHOD FOR FORMING PATTERN AND METHOD FOR FABRICATING SEMICONDUCTOR DEVICE USING THE SAME

(71) Applicants: Soo-Yeon Jeong, Hwaseong-si (KR); Dong-Kwon Kim, Yongin-si (KR); Do-Hyoung Kim, Hwaseong-si (KR); Myeong-Cheol Kim, Suwon-si (KR)

(72) Inventors: Soo-Yeon Jeong, Hwaseong-si (KR); Dong-Kwon Kim, Yongin-si (KR); Do-Hyoung Kim, Hwaseong-si (KR); Myeong-Cheol Kim, Suwon-si (KR)

(21) Appl. No.: 13/493,321

(22) Filed: Jun. 11, 2012

(30) Foreign Application Priority Data
Jul. 20, 2011 (KR) 10-2011-0072046

(51) Int. Cl. H01L 21/311; H01L 21/768

(52) U.S. Cl. 438/672; 438/702; 438/597; 257/E21.257; 257/E21.577; 257/E21.586

(57) ABSTRACT

There is provided a method for forming a pattern comprising, forming a first layer on an underlying layer including a substrate, forming a first mask pattern including a first opening pattern on the first layer, and forming a second mask pattern including a second opening pattern on the first mask pattern, wherein the second opening pattern includes a first region overlapping the first opening pattern and a second region not overlapping the first opening pattern, and etching is performed using the second mask pattern such that a third opening pattern corresponding to the first region and exposing an upper surface of the underlying layer is formed in the first layer, and a fourth opening pattern corresponding to the second region is formed in the first mask pattern.

### CROSS-REFERENCE TO RELATED APPLICATION

This application claims priority from Korean Patent Application No. 10-2011-0072046 filed on Jul. 20, 2011 in the Korean Intellectual Property Office, and all the benefits accruing therefrom under 35 U.S.C. 119. The contents of Korean Patent Application No. 10-2011-0072046 in its entirety are herein incorporated by reference.

### BACKGROUND

Embodiments relate to a method for forming a pattern and a method for fabricating a semiconductor device using the same.

### SUMMARY

According to an embodiment, there is provided a method for forming a pattern, the method including forming a first layer on an underlying layer on a substrate, forming a first mask pattern including a first opening pattern on the first layer, forming a second mask pattern including a second opening pattern on the first mask pattern, the second opening pattern including a first region overlapping the first opening pattern and a second region not overlapping the first opening pattern, and performing etching using the second mask pattern such that a third opening pattern corresponding to the first region and exposing an upper surface of the underlying layer is formed in the first layer, and a fourth opening pattern corresponding to the second region is formed in the first mask pattern.

The third opening pattern and the fourth opening pattern may be formed by an in-situ etching process. The third opening pattern and the fourth opening pattern may be formed simultaneously.

The method may further include forming a planarization layer after forming the first mask pattern and before forming the second mask pattern. The planarization layer may further include a spin-on hardmask (SOH).

The first mask pattern may be formed of a material having higher etching selectivity than that of the first layer. The first mask pattern may include titanium nitride (TiN).

According to an embodiment, there is provided a method for fabricating a semiconductor device, the method including sequentially forming a first metal wiring and an insulating layer on a substrate, forming a first mask pattern including a first opening pattern on the first insulating layer, forming a second mask pattern including a second opening pattern on the first mask pattern, the second opening pattern including a first region overlapping the first opening pattern and a second region not overlapping the first opening pattern, and performing etching using the second mask pattern such that a third opening pattern corresponding to the first region and exposing an upper surface of the first metal wiring is formed in the first insulating layer, and a fourth opening pattern corresponding to the second region is formed in the first mask pattern.

The third opening pattern and the fourth opening pattern may be formed by an in-situ etching process. The third opening pattern and the fourth opening pattern may be formed simultaneously.

The method may further include forming a planarization layer after forming the first mask pattern and before forming the second mask pattern. The planarization layer may include a spin-on hardmask (SOH).

The first mask pattern may be formed of a material having higher etching selectivity than the first insulating layer. The first mask pattern may include titanium nitride (TiN). The first insulating layer may include a low dielectric constant material.

According to an embodiment, there is provided a method of forming a patterned structure, the method including sequentially forming a metal wiring, an etch-stop layer, and an insulating layer on a substrate, forming a first mask pattern on the insulating layer, the first mask pattern including a first opening pattern, forming a planarization layer on the first mask pattern, forming a second mask pattern including a second opening pattern on the planarization layer, the second opening pattern including a first region overlapping the first opening pattern and the metal wiring and a second region not overlapping the first opening pattern, and performing etching using the second mask pattern to form the patterned structure, the patterned structure including a contact hole corresponding to the first region and extending to expose the metal wiring, and a trench corresponding to the second region in the first mask pattern.

The insulating layer may include a low dielectric constant material. The first mask pattern includes titanium nitride (TiN). The planarization layer may include a spin-on hardmask (SOH). The performing of the etching using the second mask pattern may be carried out by an in situ etching process. The method may further include filling the contact hole and the trench with a conductive metal.

### BRIEF DESCRIPTION OF THE DRAWINGS

Features will become apparent to those of ordinary skill in the art by describing in detail exemplary embodiments with reference to the attached drawings in which:

FIG. 1 illustrates a flowchart showing a method for forming a pattern in accordance with an embodiment;

FIGS. 2, 3, 4A, 4B, 5, 6A, 7, 8, 9A, 9B, and 10 illustrate stages of the method for forming a pattern shown in FIG. 1; FIG. 6B illustrates an implementation different from that of FIG. 6A;

FIG. 11 illustrates a flowchart showing a method for fabricating a semiconductor device in accordance with an embodiment;

FIG. 12 illustrates a plan view showing a second mask pattern including a second opening pattern formed in S220 of FIG. 11;

FIG. 13 illustrates a cross-sectional view taken along line C-C′ of FIG. 12;

FIG. 14 illustrates a perspective view of a semiconductor device after the stages illustrated in FIG. 11 have been completed;

FIG. 15 illustrates a perspective view of the semiconductor device of FIG. 14 after depositing an interlayer wiring metal and via filling metal on portions corresponding to a second metal wiring and via.

FIG. 16 illustrates a flowchart showing stages of a method for fabricating a semiconductor device in accordance with another embodiment;

FIG. 17 illustrates a plan view showing a second mask pattern including a second opening pattern formed in S320 of FIG. 15;

FIG. 18 illustrates a cross-sectional view taken along line D-D′ of FIG. 16;

FIG. 19 illustrates a perspective view of a semiconductor device after the stages of FIG. 15 have been completed; and

FIG. 20 illustrates a diagram for explaining a method for fabricating a semiconductor device in accordance with still another embodiment.

### DETAILED DESCRIPTION

Example embodiments will now be described more fully hereinafter with reference to the accompanying drawings; however, they may be embodied in different forms and should not be construed as limited to the embodiments set forth herein.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

It will be understood that, although the terms first, second, etc. may be used herein to describe various elements, these elements should not be limited by these terms. These terms are only used to distinguish one element from another element. Thus, for example, a first element, a first component, or a first section discussed below could be termed a second element, a second component, or a second section without departing from the teachings.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

Unless defined otherwise, all technical and scientific terms used herein have the same meaning as commonly understood by one of ordinary skill in the art to which this invention belongs. It is noted that the use of any and all examples, or exemplary terms provided herein is intended merely to better illuminate the invention and is not a limitation on the scope of the invention unless otherwise specified. Further, unless defined otherwise, all terms defined in generally used dictionaries may not be overly interpreted.

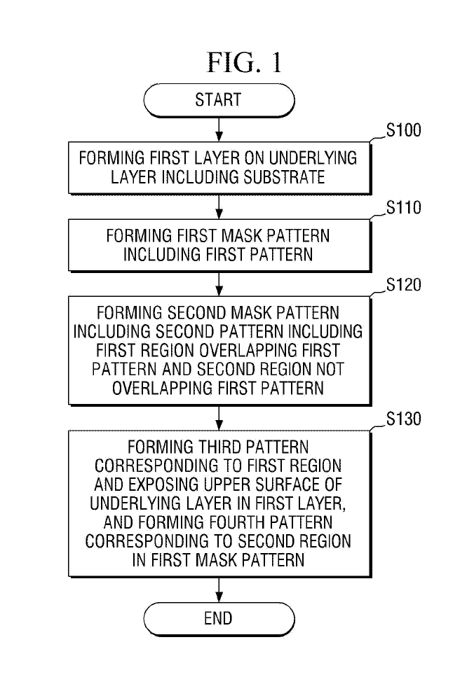

Hereinafter, a method for forming a pattern in accordance with an embodiment will be described with reference to FIGS. 1 to 10.

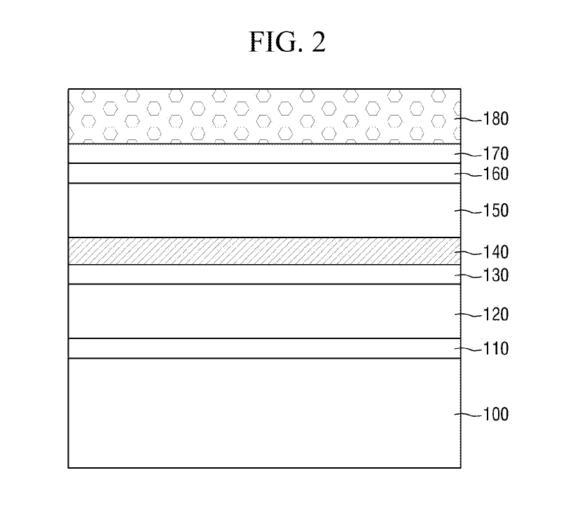

FIG. 1 is a flowchart showing a method for forming a pattern in accordance with an embodiment. FIGS. 2 to 10 illustrate the stages of the method for forming a pattern shown in FIG. 1. Referring to FIGS. 1 and 2, a first layer 120 is formed on an underlying layer 110 on a substrate 100 (S100). Referring to FIG. 2, the underlying layer 110, the first layer 120, a first adhesive layer 130, a first mask 140, a second mask 150, a second adhesive layer 160, a first anti-reflection layer 170, and a first photoresist layer 180 are sequentially formed on the substrate 100.

Specifically, the substrate 100 may be a silicon substrate or a silicon-on-insulator (SOI) substrate. In other implementations, the substrate 100 may include other materials such as silicon germanium, indium antimonide, lead telluride, indium arsenide, indium phosphide, gallium arsenide, or gallium antimonide, as examples.

The underlying layer 110 may be an etch-stop layer, and may be formed of, e.g., SiC, SiOC, SiN, SiON, SiCN or a combination thereof. In other implementations, the etch-stop layer may include other suitable materials. In other implementations, the underlying layer may include a plurality of layers instead of a single layer. The underlying layer 110 may be formed by using, e.g., a chemical vapor deposition (CVD) process or atomic layer deposition (ALD) process. The underlying layer 110 may be omitted for processing simplicity. In this case, the substrate may be an underlying layer.

The first layer 120 may be formed as an insulating layer, e.g., a silicon oxide layer. The insulating layer may be formed by, e.g., a CVD or an ALD method. There may be slight differences according to the design rule of a semiconductor device.

The first adhesive layer 130 and the second adhesive layer 160 may be formed of silicon oxynitride (SiON), and may be formed by using, e.g., a CVD process or ALD process. In a case where the adhesivity is weak due to a large difference in permittivity between upper and lower layers, an adhesive layer may be interposed therebetween to increase the adhesivity between the upper and lower layers.

The first mask 140 may mainly include metal or a metal compound, e.g., Ti, Ta, TiN, TaN, TiC or a combination thereof, or other suitable materials. Further, the first mask 140 may be formed by, e.g., CVD, ALD, physical vapor deposition (PVD) or sputtering.

The first mask 140 is a portion where a first mask pattern and a final mask pattern are formed. The first mask 140 may be formed of a material having a high etching selectivity with respect to the first layer 120. Thus, when the first layer 120 is etched, the first mask 140 may be not substantially etched or may have an etching rate that is much lower than the etching rate of the first layer 120.

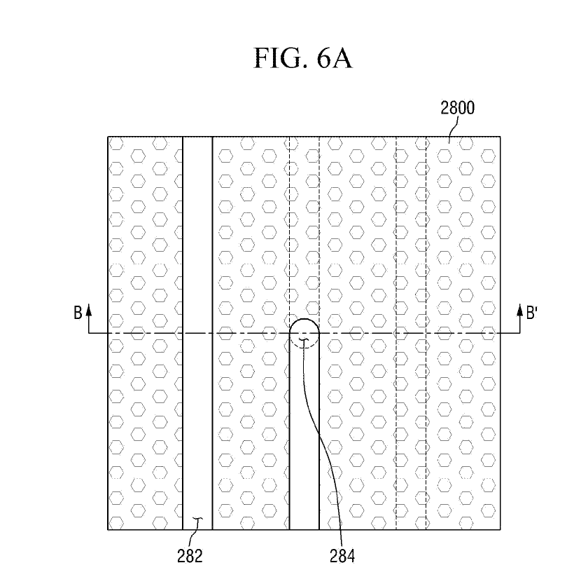

The second mask 150 may be formed as a sacrificial layer for etching. The second mask 150 may be formed as, e.g., an organic layer such as a spin on hardmask (SOH) layer, or an oxide layer such as a tonen silazene (TOSZ) layer, spin on glass (SOG) layer, F-CVD layer and undoped silica glass (USG) layer, or other suitable layers. A function of the second mask 150 will be described below with reference to FIG. 5.

The first anti-reflection layer 170 may be formed to prevent an undesired pattern from being formed by light reflected from a lower layer located below the photoresist layer in an exposure process. The anti-reflection layer may be omitted if a layer located below the anti-reflection layer has an anti-reflection function, or may be omitted for processing simplicity.

The first photoresist layer 180 may be formed as, e.g., a positive photoresist or a negative photoresist. The photoresist may be formed using various materials according to the type of a light source used in an exposure process and the shape of a pattern to be formed.

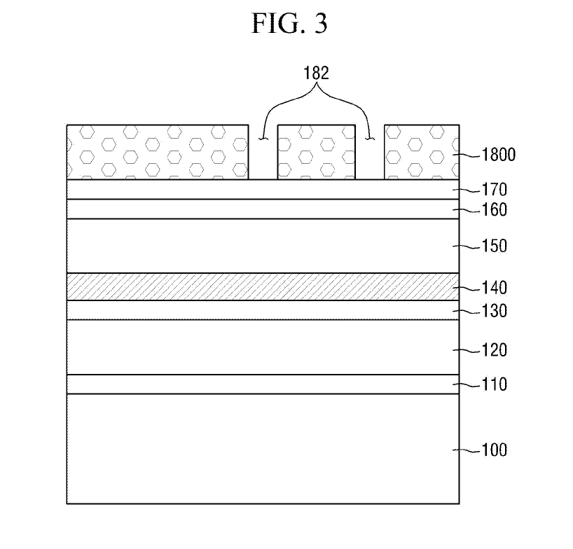

Referring to FIG. 3, a region of the first photoresist layer 180 for formation of a first opening pattern is exposed to light using a first exposure mask (not shown). Then, the first photoresist layer is developed to form a first photoresist layer pattern 1800 including openings 182.

Specifically, e.g., ArF (193 nm), KrF (248 nm), extreme ultra violet (EUV), vacuum ultra violet (VUV, 157 nm), E-beam, X-ray or ion beam, or other suitable light sources may be used as an exposure light source.

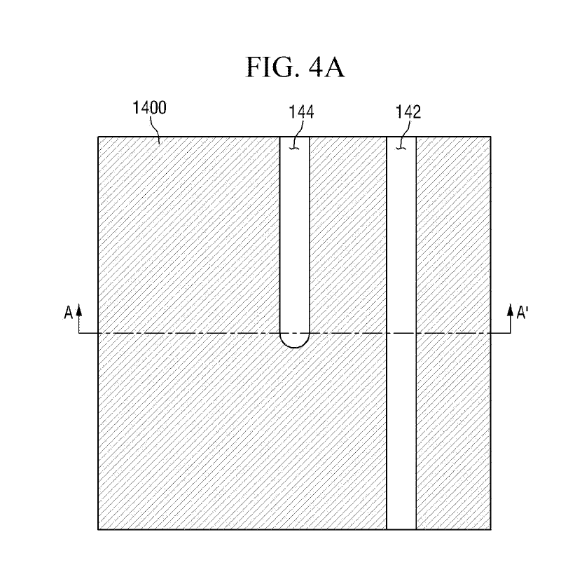

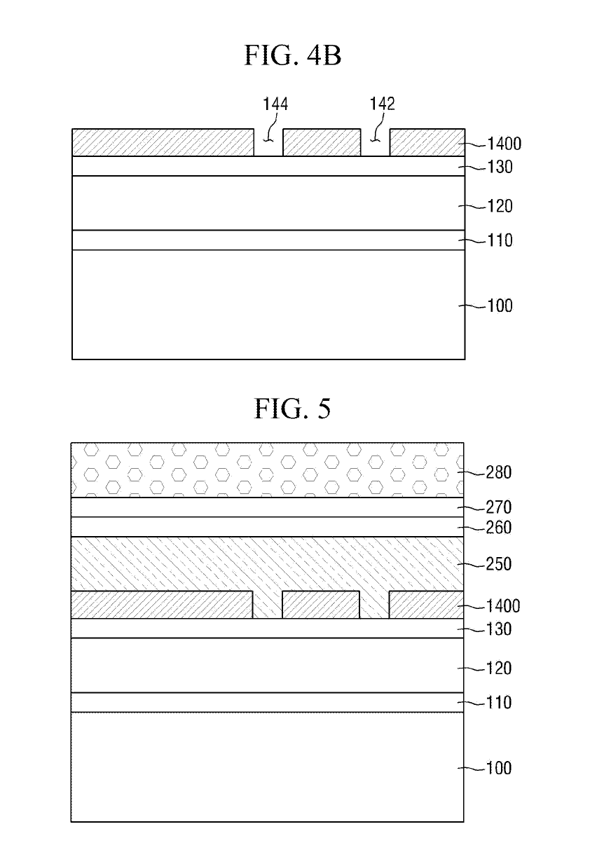

Referring to FIGS. 1, 4A and 4B, a first mask pattern 1400 including a first opening pattern 142 and 144 is formed (S110). Thus, the first mask pattern 1400 including the first opening pattern 142 and 144 exposing the first adhesive layer 130 is formed in the first mask at positions corresponding to the openings 182 of FIG. 3.

FIG. 4A is a plan view of the first mask pattern 1400. FIG. 4B is a cross-sectional view taken along line A-A′ of FIG. 4A.

An etching process for forming the first mask pattern 1400 may be wet etching, dry etching or a combination thereof. For example, dry etching may be used for anisotropic etching. In a dry etching process, an etching target layer may be etched by using an appropriate source gas. The etching of the etching target layer may be ended by end-point detection (EPD) for the etching target layer. If there are a plurality of etching target layers, the etching target layers may be etched while varying the appropriate source gas and etching conditions for each etching target layer, or the target layers may be etched by using a mixture of source gases appropriate for the respective etching target layers.

Referring to FIG. 3, after the first anti-reflection layer 170 is etched using the first photoresist layer pattern 1800 as a mask, a first anti-reflection layer pattern may be formed by removing the first photoresist layer pattern 1800. In this way, patterns may be sequentially formed in the second adhesive layer 160 and the second mask 150, and the first mask 140 may be etched by using, as a mask, the pattern formed in the second mask 150. Then, the first mask pattern 1400 including the first opening pattern 142 and 144 may be formed by removing the second mask 150. In another implementation, the first mask pattern 1400 may be formed in-situ using the first photoresist layer pattern 1800 as a mask without repeated steps of etching and removing a pattern used as a mask. The above process is merely an example to describe the embodiment, and other suitable processes of forming the first mask pattern 1400 may be used.

Referring to FIGS. 1 and 5 to 7, a second mask pattern 2800 including a second opening pattern 282 and 284 is formed on the first mask pattern 1400. In this case, the second opening pattern includes a first region 284 overlapping the first opening pattern 142 and 144 and a second region 282 not overlapping the first opening pattern 142 and 144 (S120).

Referring to FIG. 5, a third mask 250, a third adhesive layer 260, a second anti-reflection layer 270 and a second photoresist layer 280 may be sequentially formed on the first mask pattern 1400.

The third mask 250, the third adhesive layer 260, the second anti-reflection layer 270 and the second photoresist layer 280 may be similar to corresponding features shown in FIG. 2. Accordingly, to avoid redundancy, the description of these features will not be repeated. The third mask 250 may be formed on the first mask pattern 1400 to planarize the irregular surface of the first mask pattern 1400. Further, it may be possible to adjust the width of the pattern formed in the first mask 140 or the first mask pattern 1400 through etching by adjusting the material and thickness of the second mask 150 of FIG. 2 and the third mask 250.

Specifically, the width of an opening of the photoresist layer pattern used as a mask in an etching process may be substantially equal to or larger than the width of the corresponding opening pattern formed in a target layer through etching. When the layers sequentially stacked on the target layer are etched, the side surfaces of the etched layers may be formed to have a slope. Accordingly, the width of the opening of the photoresist layer pattern may be larger than the width of the corresponding opening pattern formed in the target layer. By adjusting the thickness or material of the layer inserted between the photoresist layer pattern and the target layer, it may be possible to adjust the width of the opening pattern formed in the target layer.

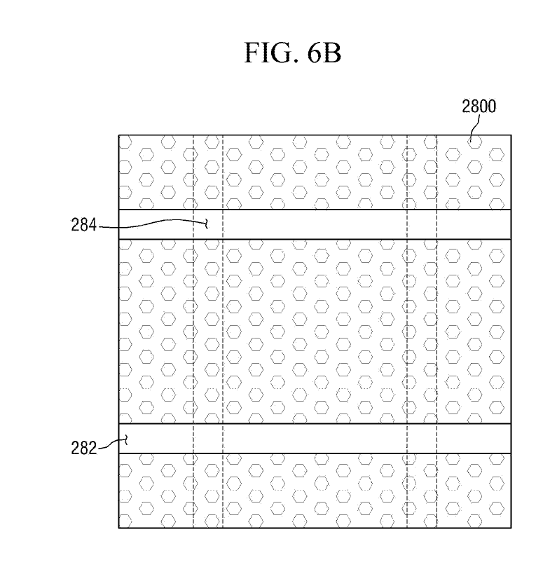

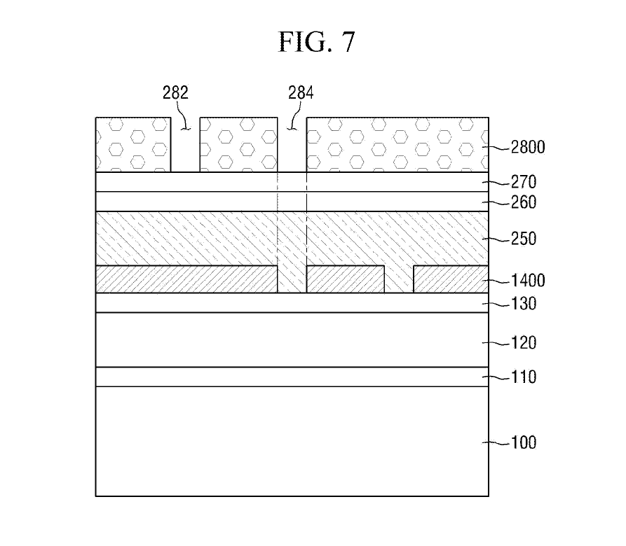

The second photoresist layer 280 may be exposed to light using a second exposure mask (not shown). Referring to FIGS. 6A to 7, the second photoresist layer 280 exposed to light may be developed to form the second mask pattern 2800 including the second opening pattern 282 and 284 exposing the second anti-reflection layer 270. The second mask pattern 2800 may include the second opening pattern 282 and 284 including the first region 284 overlapping the first opening pattern and the second region 282 not overlapping the first opening pattern.

Although the second mask pattern 2800 may be formed in the second photoresist layer 280 in the embodiment, other suitable methods of forming the second mask pattern 2800 may be used. For example, the second mask pattern 2800 may be formed in the second anti-reflection layer 270, the third adhesive layer 260, the third mask 250 or a combination thereof.

FIG. 6A is a plan view of the second mask pattern 2800 including the second opening pattern 282 and 284. A portion represented by dotted lines is the first opening pattern 142 and 144 (see FIGS. 4A, 4B and 5) formed below the second mask pattern 2800. In the second opening pattern 282 and 284, a portion overlapping the first opening pattern is the first region 284, and a portion not overlapping the first opening pattern is the second region 282. FIG. 6B illustrates another implementation, different from that of FIG. 6A, in which a first opening pattern and a second opening pattern cross each other, the first region 284 being located where the first opening pattern and the second opening pattern intersect and overlap and the second region 282 being located where the first opening pattern and the second opening pattern do not overlap.

FIG. 7 illustrates a cross-sectional view taken along B-B′ of FIG. 6A. As illustrated in FIG. 7, the first opening pattern 144 is present below a portion of the second opening pattern corresponding to the first region 284, and the first opening pattern is not present below a portion of the second opening pattern corresponding to the second region 282.

Referring to FIGS. 1 and 10, a third opening pattern 244 exposing the upper surface of the underlying layer 110 and corresponding to the first region 284 is formed in the first layer 120, and a fourth opening pattern 242 corresponding to the second region 282 is formed in the first mask pattern 1400 (S130).

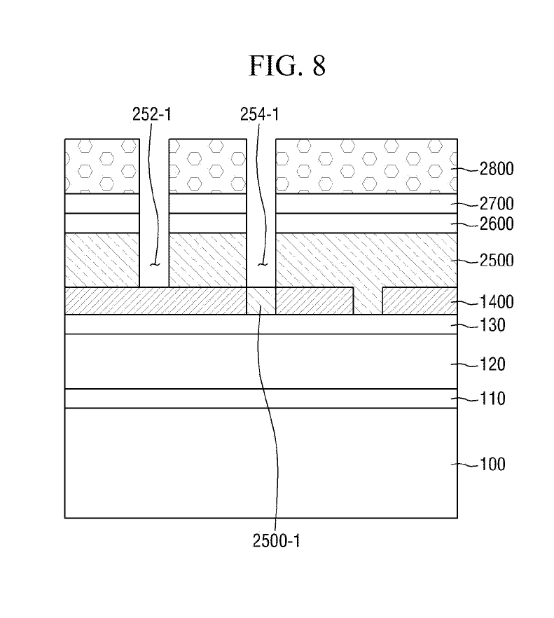

Referring to FIG. 8, in forming the pattern shown in FIG. 10, the second mask pattern 2800 may be used as a mask without repeated steps of etching and removing a pattern used as a mask. Accordingly, a fifth opening pattern 254-1 corresponding to the first region 284 and a sixth opening pattern 252-1 corresponding to the second region 282 may be formed in-situ in the third mask 250.

In another implementation, after the second anti-reflection layer 270 is etched using the second mask pattern 2800 as a mask, a second anti-reflection layer pattern 2700 may be formed by removing the second mask pattern 2800. In this way, patterns corresponding to the second opening pattern may be sequentially formed in the third adhesive layer 260 and the third mask 250 to form a patterned third adhesive layer 2600 and a patterned third mask 2500.

Referring to FIGS. 8 to 9B and 10, the patterned third mask 2500 may be exposed by removing the second mask pattern 2800, the second anti-reflection layer pattern 2700, and the third adhesive layer pattern 2600.

Subsequently, using the patterned third mask 2500 as a mask, an opening pattern 254 exposing the upper surface of the underlying layer 110 and corresponding to the first region 284 (see FIG. 7) may be formed in the first layer 120 and an opening pattern 252 corresponding to the second region 282 (see FIG. 7) may be formed in the first mask pattern 1400 in an in-situ manner. Other suitable methods may be used.

Referring to FIG. 10, the first opening pattern 142, the third opening pattern 244 and the fourth opening pattern 242 may be formed in the first mask pattern 1400 and the first layer 120 by removing the patterned third mask 2500. The first opening pattern 142 is formed in S110 of FIG. 1 (see also FIG. 4B), and the fourth opening pattern 242 and the third opening pattern 244 are formed in S130 of FIG. 1 (see FIGS. 8 to 10).

In the method of forming the third opening pattern 244 and the fourth opening pattern 242 in an in-situ manner, the first mask pattern 1400 disposed below the sixth opening pattern 252-1 may be used as an etch stop mask. In the embodiment, for example, the first mask pattern 1400 may be formed of titanium nitride (TiN), and the third mask 150 may be formed as a spin-on hardmask (SOH). Further, while a third mask portion 2500-1 located below the fifth opening pattern 254-1 (see FIG. 8) is etched, the patterned third mask 2500 may also be etched. Accordingly, the thickness of the patterned third mask 2500 located on the first mask pattern 1400 may be greater than the thickness of the third mask portion 2500-1 located below the fifth opening pattern 254-1.

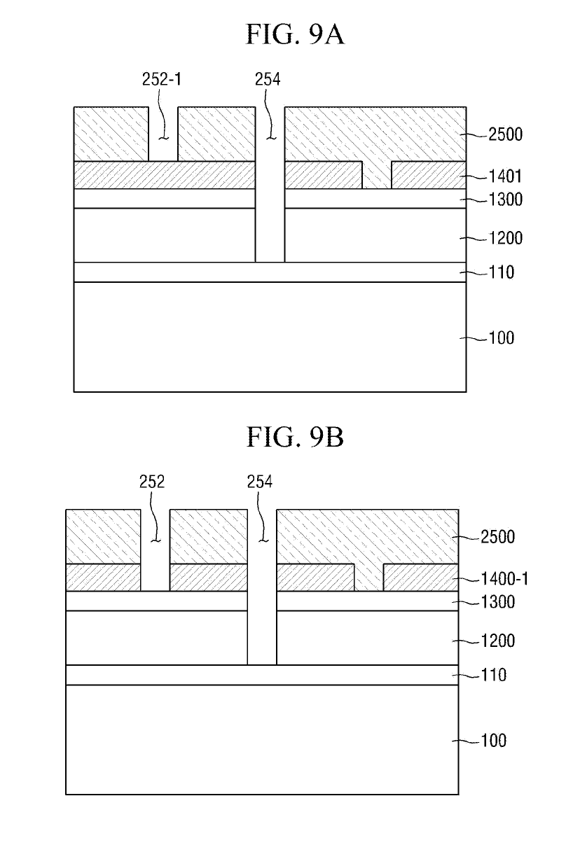

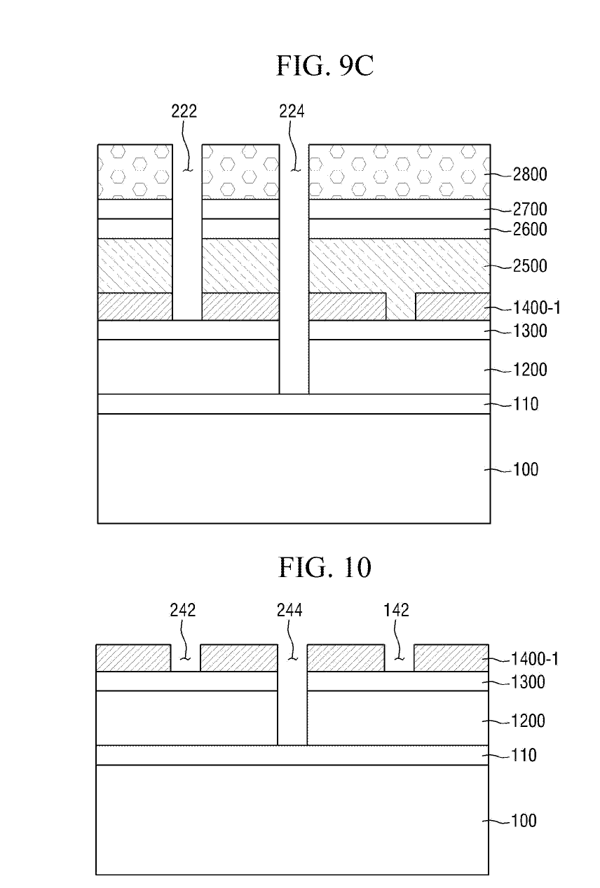

Etching may be performed using a source gas or a combination of source gases having a higher etching selectivity to SOH, the first adhesive layer and the first layer than TiN. As an etching source gas, for example, a mixture of oxygen/nitrogen (O₂/N₂) may be used for the SOH, and a fluoride gas such as tetrafluoromethane (CF₄) may be used for the first adhesive layer 130 and the first layer 120. The third mask portion 2500-1 located below the fifth opening pattern is etched using a mixture of oxygen/nitrogen (O₂/N₂) as a source gas. In this case, the first mask pattern 1400 is not substantially etched. Subsequently, the first adhesive layer 130 and the first layer 120 are etched using CF₄ as a source gas until the upper surface of the underlying layer 110 is exposed, thereby forming the opening pattern 254 (see FIG. 9A) corresponding to the first region 284 (see FIG. 7) in the first layer 120. In an implementation, the opening pattern 254 corresponding to the first region 284 may be formed in the first layer 120 without changing the etching conditions by combining a mixture of oxygen/nitrogen (O₂/N₂) with CF₄.

Subsequently, the first mask pattern 1400 located below the sixth opening pattern 252-1 may be etched using a source gas having high etching selectivity to TiN, e.g., a chlorine-based gas or a combination thereof. In the embodiment, chlorine (Cl₂) may be used as an etching source gas of TiN. Etching may be performed until the first adhesive layer 130 is exposed, thereby forming the opening pattern 252 (see FIG. 9B) corresponding to the second region 282 (see FIG. 7) in the first mask pattern 1400. Subsequently, the third opening pattern 244 and the fourth opening pattern 242 may be formed by removing the patterned third mask 2500.

Referring to FIGS. 8, 9B and 10, another method for forming the third opening pattern 244 and the fourth opening pattern 242 in an in-situ manner will be described. In this implementation, the method may proceed from the stage shown in FIG. 8 to the stage shown in FIG. 9B, while omitting the stage shown in FIG. 9A. While the third mask portion 2500-1 located below the fifth opening pattern 254-1 (see FIG. 8) is etched, the patterned third mask 2500 may also be etched. Accordingly, the thickness of the patterned third mask 2500 located on the first mask pattern 1400 may be larger than the thickness of the third mask portion 2500-1 located below the fifth opening pattern 254-1.

The third mask portion 2500-1 located below the fifth opening pattern 254-1 may be removed by using a mixture of oxygen/nitrogen (O₂/N₂) as an etching source gas. Subsequently, a combination ratio of etching source gases may be determined considering the thicknesses of the first adhesive layer 130 and the first layer 120 and the thickness of the first mask pattern 1400, and etching may be performed using a combination of source gases. The opening pattern 254 exposing the upper surface of the underlying layer 110 and corresponding to the first region 284 may be formed in the first layer 120 and, at the same time, the opening pattern 252 corresponding to the second region 282 may be formed in the first mask pattern 1400 by combining Cl₂, serving as an etching source gas of TiN, with CF₄, serving as a source gas of the first adhesive layer 130 and the first layer 120. Subsequently, the third opening pattern 244 and the fourth opening pattern 242 may be formed by removing the patterned third mask 2500.

Referring to FIGS. 8, 9C and 10, still another method for forming the third opening pattern 244 and the fourth opening pattern 242 in an in-situ manner will be described. In this implementation, the third opening pattern 244 and the fourth opening pattern 242 may be formed without removing the second mask pattern 2800, the second anti-reflection layer pattern 2700 and the third adhesive layer pattern 2600. For example, the method may proceed from the stage shown in FIG. 8 to the stage shown in FIG. 9C, while omitting the stages shown in FIG. 9A and FIG. 9B

The third mask portion 2500-1 located below the fifth pattern 254-1 (see FIG. 8) may be removed using a mixture of oxygen/nitrogen (O₂/N₂) as an etching source gas. Subsequently, the first adhesive layer 130 and the first layer 120 may be etched using CF₄ as a source gas until the upper surface of the underlying layer 110 is exposed, thereby forming an opening pattern 224 (see FIG. 9C) in the first layer 120 at a position corresponding to the first region 284. Subsequently, the first mask pattern 1400 located below the sixth opening pattern 252-1 (see FIG. 8) may be etched using Cl₂ as an etching source gas. Etching may be performed until the first adhesive layer 130 is exposed to form an opening pattern 222 (see FIG. 9C) in the first mask pattern 1400 at a position corresponding to the second region 282. The second mask pattern 2800, the second anti-reflection layer pattern 2700, the third adhesive layer pattern 2600, the patterned third mask 2500 may be sequentially removed to thereby form the third opening pattern 244 and the fourth opening pattern 242.

In still another method for forming the third opening pattern 244 and the fourth opening pattern 242 in an in-situ manner, the third opening pattern 244 and the fourth opening pattern 242 may be formed at the same time without removing the second mask pattern 2800, the second anti-reflection layer pattern 2700 and the third adhesive layer pattern 2600.

The third mask portion 2500-1 located below the fifth opening pattern 254-1 may be removed by using a mixture of oxygen/nitrogen (O₂/N₂) as an etching source gas. Subsequently, a combination ratio of etching source gases may be determined considering the thicknesses of the first adhesive layer 130 and the first layer 120 and the thickness of the first mask pattern 1400, and etching may be performed using a combination of source gases. Thus, the opening pattern 224 (see FIG. 9C) exposing the upper surface of the underlying layer 110 and corresponding to the first region 284 may be formed in the first layer 120 and, at the same time, the opening pattern 222 (see FIG. 9C) corresponding to the second region 282 may be formed in the first mask pattern 1400 by combining Cl₂ serving as an etching source gas of TiN with CF₄ serving as a source gas of the first adhesive layer and the first layer. Subsequently, the third opening pattern 244 and the fourth opening pattern 242 may be formed by sequentially removing the second mask pattern 2800, the second anti-reflection layer pattern 2700, the third adhesive layer pattern 2600 and the patterned third mask 2500.

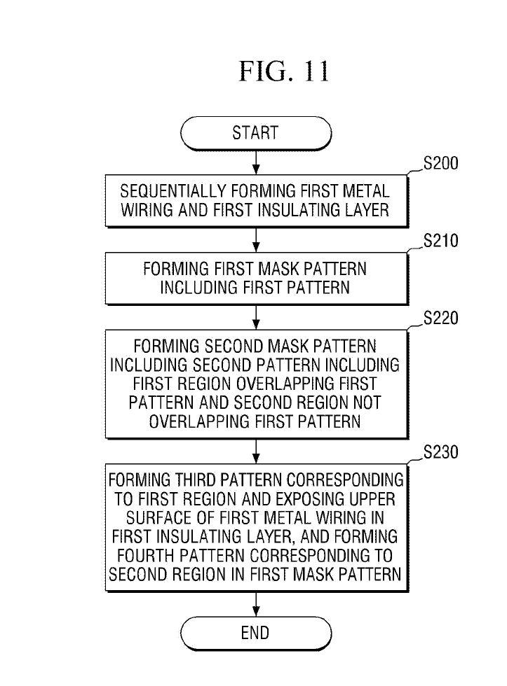

FIGS. 11 to 14 are diagrams for explaining stages of a method for fabricating a semiconductor device in accordance with an embodiment. The method for fabricating a semiconductor device illustrated in FIGS. 11 to 14 employs the method for forming a pattern illustrated in FIGS. 1 to 10.

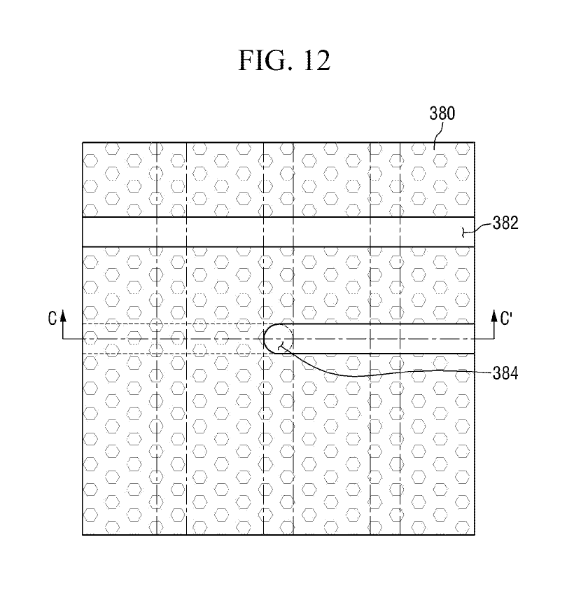

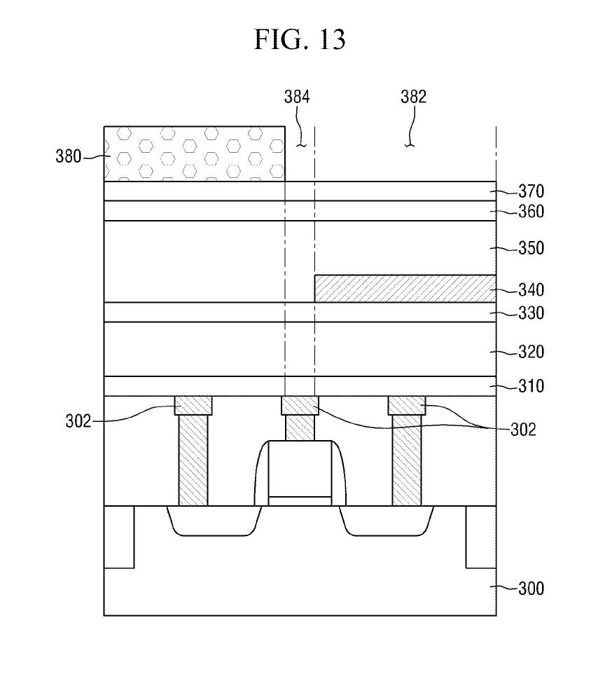

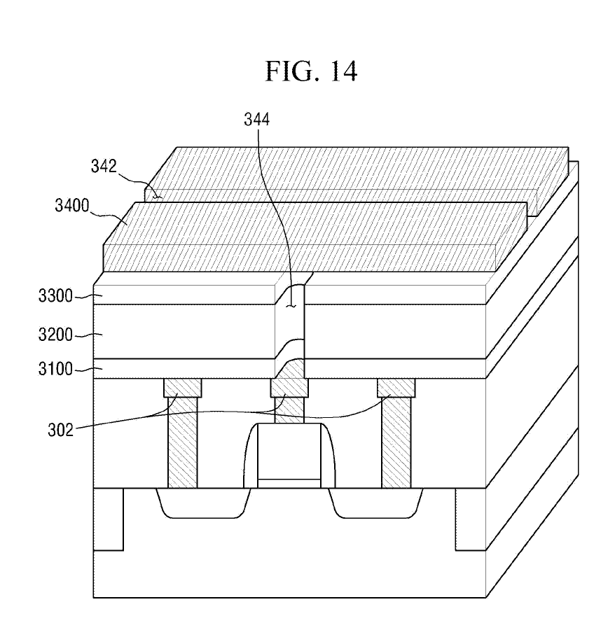

FIG. 11 is a flowchart showing a method for fabricating a semiconductor device in accordance with an embodiment. FIG. 12 is a plan view showing a second mask pattern including a second opening pattern formed in S220 of FIG. 11. FIG. 13 is a cross-sectional view taken along line C-C′ of FIG. 12. FIG. 14 is a perspective view of a semiconductor device after the method illustrated FIG. 11 has been completed.

Referring to FIGS. 11 and 13, a first metal wiring 302 and a first insulating layer 320 are sequentially formed on a substrate 300 (S200). Subsequently, a first mask pattern including a first opening pattern is formed on the first insulating layer 320 (S210).

Referring to FIG. 13, the first metal wiring 302, an etch stop layer 310, the first insulating layer 320, a first adhesive layer 330, a first mask, a second mask, a second adhesive layer, a first anti-reflection layer, and a first photoresist layer may be sequentially formed on the substrate 300.

Specifically, the first metal wiring 302 may be formed of, e.g., Al or Cu, or other suitable materials. The first metal wiring 302 may be formed by different processes according to a material of the metal wiring. For example, Al wiring may be formed by PVD, CVD, sputtering or the like, and Cu wiring may be formed by electroplating or the like.

The first insulating layer 320 may function as, e.g., an interlayer isolation. The first insulating layer 320 may be formed to include an insulating material different from that of the etch stop layer 310, e.g., silicon oxide or a low dielectric constant material. The first insulating layer 320 may be doped with impurities in high concentration. The low dielectric constant material may be, e.g., fluorinated silica glass (FSG), a carbon-doped silicon oxide, an aerogel, an amorphous fluorocarbon, a porous polymeric material, or a combination thereof. Other suitable materials may be used.

Since the substrate 300, the etch stop layer 310, the first adhesive layer 330, the first mask, the second mask, the second adhesive layer, the first anti-reflection layer, and the first photoresist layer may be similar to corresponding features described above, a description thereof will not be repeated. The etch-stop layer 310 may have the characteristics of the underlying layer 110 of FIG. 2.

Subsequently, a region for forming the first opening pattern on the first photoresist layer may be exposed to light using a first exposure mask. The first photoresist layer may be developed to form the first photoresist layer pattern. Then, etching may be performed using the first photoresist layer pattern as a mask, thereby forming a first mask pattern 340 including the first opening pattern in the first mask.

Referring to FIGS. 11 to 13, a second mask pattern 380 including a second opening pattern 382 and 384 may be formed on the first mask pattern 340. The second opening pattern 382 may include a first region 384 overlapping the first opening pattern and a second region 382 not overlapping the first opening pattern (S220).

A third mask 350, a third adhesive layer 360, a second anti-reflection layer 370 and a second photoresist layer may be sequentially formed on the first mask pattern 340. The third mask 350, the third adhesive layer 370, the second anti-reflection layer 370 and the second photoresist layer may be similar to corresponding features described above. Accordingly, a description thereof will not be repeated.

Referring to FIGS. 12 and 13, the second photoresist layer may be exposed to light using a second exposure mask (not shown). The second photoresist layer exposed to light for the second opening pattern may be developed to thereby form the second mask pattern 380 including the second opening pattern 382 and 384 exposing the second anti-reflection layer 370. The second mask pattern 380 may include the first region 384 overlapping the first opening pattern and the second region 382 not overlapping the first opening pattern.

In the embodiment, the second mask pattern 380 including the second opening pattern may be formed using the second photoresist layer. Other suitable method for forming the second mask pattern 380 may be used. For example, the second mask pattern 380 may be formed using the second anti-reflection layer 370, the third adhesive layer 360, the third mask 350 or a combination thereof.

A portion indicated by dotted lines of FIG. 12 represents the first opening pattern formed below the second mask pattern 380. A portion indicated by dashed dotted lines of FIG. 12 in which the first and second opening patterns intersect each other represents the first metal wiring 302 formed below the first mask pattern 340. In the second opening pattern 382, a portion overlapping the first opening pattern and the first metal wiring 302 is the first region 384, and a portion not overlapping the first opening pattern is the second region 382. FIG. 13 illustrates that the first opening pattern is formed below a portion of the second opening pattern corresponding to the first region 384, and the first opening pattern is not formed below a portion of the second opening pattern corresponding to the second region 382.

Referring to FIGS. 11 and 14, a third opening pattern 344 corresponding to the first region and exposing the upper surface of the first metal wiring 302 is formed in the first insulating layer 320 (see FIG. 13), and a fourth opening pattern 342 corresponding to the second region may be formed in the first mask pattern 340 (see FIG. 13) (S230).

Referring to FIG. 14, an opening pattern corresponding to the first region 384 (see FIG. 13) and exposing the etch stop layer 310 may be formed and the third opening pattern 344 exposing the upper surface of the first metal wiring 302 may be formed. Further, the fourth opening pattern 342 corresponding to the second region 382 (see FIG. 13) may be formed in-situ. Other suitable methods for forming the third opening pattern 344 and the fourth opening pattern 342 may be used. The opening pattern formed on the left side of the third opening pattern 344 of FIG. 14 corresponds to the first opening pattern formed in S210. The third opening pattern 344 and the fourth opening pattern 342 including the opening pattern formed on the right side of the third opening pattern 344 in FIG. 14 are formed in S230. The fourth opening pattern 342 and the first opening pattern included in the first mask pattern 340 correspond to a portion where a second metal wiring 3420 is formed. The third opening pattern 344 corresponds to a via 3440 connecting the first metal wiring 302 with the second metal wiring.

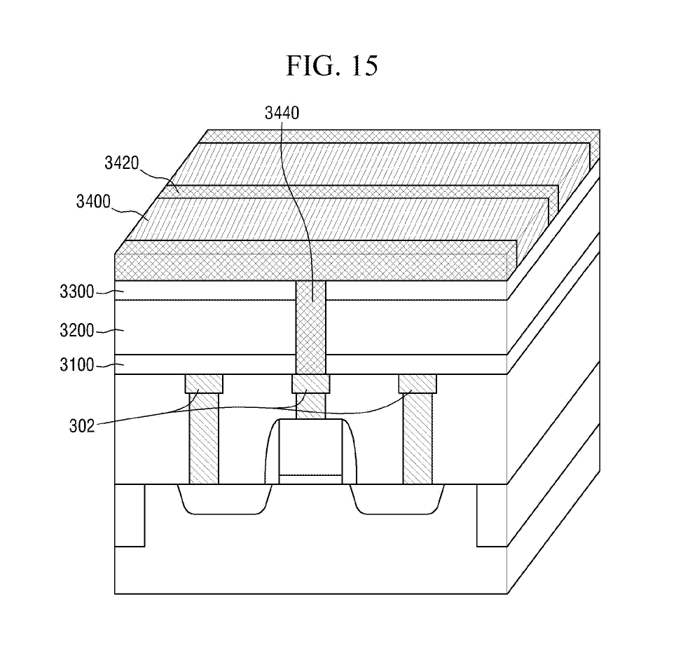

Referring to FIG. 15, the semiconductor device may be fabricated by depositing interlayer wiring metal and via filling metal on the corresponding portions to form the second metal wiring 3420 and the via 3440.

In the method for forming the third opening pattern 344 and the fourth opening pattern 342 in an in-situ manner, the third opening pattern 344 and the fourth opening pattern 342 may be sequentially formed by varying an etching source gas without removing the second mask pattern. In another implementation, the third opening pattern 344 and the fourth opening pattern 342 may be formed at the same time by a combination of etching source gases. Thereafter, layers existing on a first mask pattern 3400 formed thereby may be removed.

In another method for forming the third opening pattern 344 and the fourth opening pattern 342 in an in-situ manner, after forming the pattern corresponding to the second opening pattern in the third mask located directly above the first mask pattern, the layers on the patterned third mask may be removed. Subsequently, the third opening pattern 344 and the fourth opening pattern 342 may be sequentially formed using the patterned third mask by varying an etching source gas, or the third opening pattern 344 and the fourth opening pattern 342 may be formed at the same time by using a combination of etching source gases. Then, the patterned third mask may be removed.

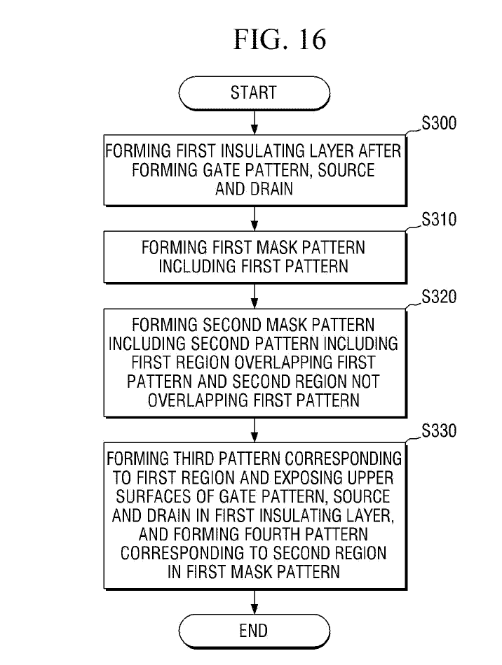

FIGS. 16 to 19 are diagrams for explaining stages of a method for fabricating a semiconductor device in accordance with another embodiment. The method for fabricating a semiconductor device illustrated in FIGS. 16 to 19 employs the method for forming a pattern illustrated in FIGS. 1 to 10. A description of similar features will not be repeated.

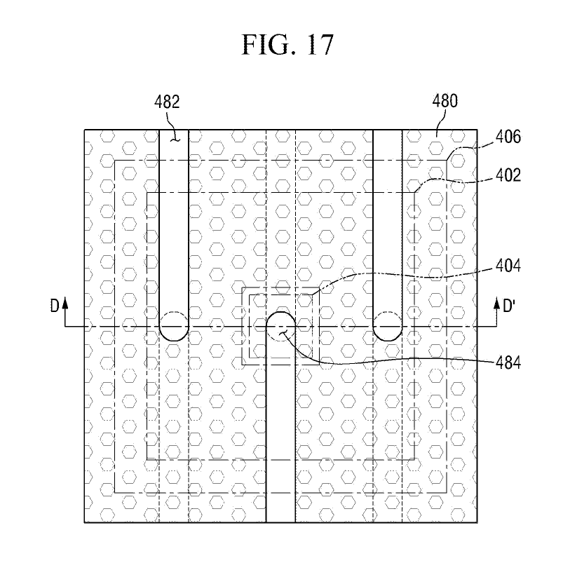

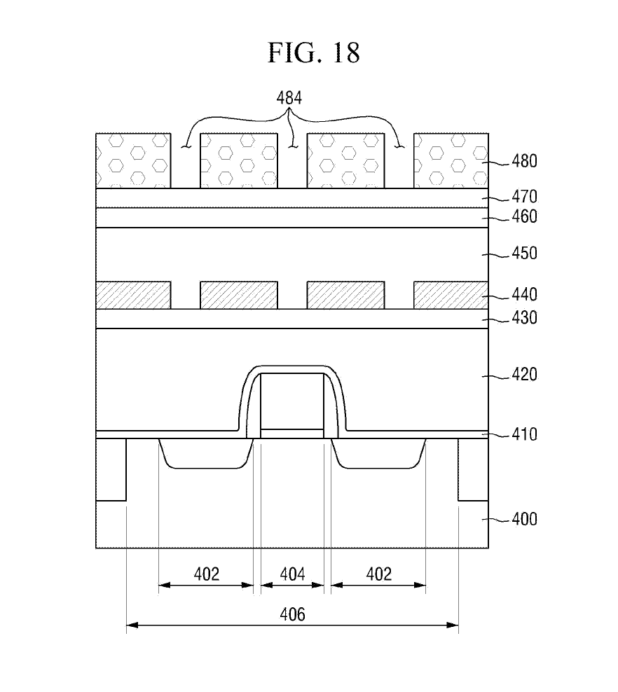

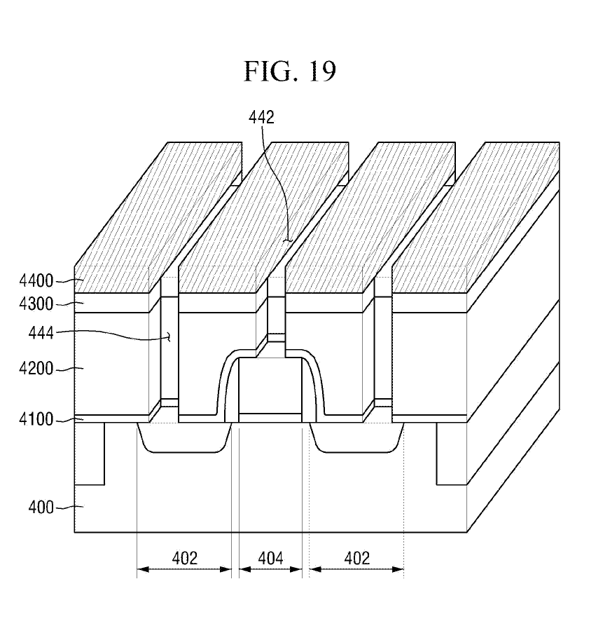

FIG. 16 is a flowchart showing a method for fabricating a semiconductor device in accordance with another embodiment. FIG. 17 is a plan view showing a second mask pattern including a second opening pattern formed in S320 of FIG. 16. FIG. 18 is a cross-sectional view taken along line D-D′ of FIG. 17. FIG. 19 is a perspective view of a semiconductor device after the method illustrated in FIG. 16 has been completed.

Referring to FIGS. 16 and 18, after a gate pattern 404 is formed on a substrate 400 and a source and drain 402 are formed on both sides of the gate pattern, a first insulating layer 420 may be formed (S300). Subsequently, a first mask pattern 440 including a first opening pattern may be formed on the first insulating layer 420 (S310).

An active region 406 may be defined on the substrate 400. The gate pattern 404 may be formed in the active region 406 and the source and drain 402 may be formed on both sides of the gate pattern. The order of forming the gate pattern 404, and the source and drain 402 may vary. The source and drain 402 may be formed by forming trenches by etching regions where the source and drain 402 are to be formed and filling up the trenches. A transistor may be formed in the active region 406 (see FIG. 18). In other implementations, other suitable structures, such as a diode, may be formed therein.

After forming the gate pattern 404 and the source and drain 402, an etch stop layer 410, the first insulating layer 420, a first adhesive layer 430, a first mask, a second mask, a second adhesive layer, a first anti-reflection layer, and a first photoresist layer may be formed thereon. Subsequently, the formed structures may be sequentially exposed to light using a first exposure mask, and developed to form the first photoresist layer pattern. Then, the first mask pattern 440 including the first opening pattern may be formed in the first mask through etching.

Referring to FIGS. 16 to 18, a second mask pattern 480 including a second opening pattern 482 and 484 may be formed on the first mask pattern 440. The second opening pattern may include a first region 484 overlapping the first opening pattern and a second region 482 not overlapping the first opening pattern (S320).

Specifically, a third mask 450, a third adhesive layer 460, a second anti-reflection layer 470 and a second photoresist layer may be sequentially formed on the first mask pattern 440. Subsequently, the second photoresist layer may be exposed to light using a second exposure mask and developed to thereby form the second mask pattern 480. The second mask pattern 480 may include the first region 484 overlapping the first opening pattern and the second region 482 not overlapping the first opening pattern. Although the second mask pattern 480 in FIGS. 17 and 18, including the second opening pattern, may be formed using a second photoresist layer, other suitable methods may be used.

FIG. 17 is a plan view of the second mask pattern 480. A portion indicated by dotted lines represents the first opening pattern formed below the second mask pattern 480. A portion indicated by dashed dotted lines represents the gate pattern 404 and the source and drain 402 formed below the first mask pattern 440. In the second opening pattern, one of the gate pattern 404 and the source and drain 402 is located below the first region 484 overlapping the first opening pattern. FIG. 18 illustrates that the first opening pattern 440 may be formed below a portion of the second opening pattern corresponding to the first region 484.

Referring to FIGS. 16 and 19, a third opening pattern 444 corresponding to the first region and exposing the upper surfaces of the gate pattern 404 and the source and drain 402 may be formed in the first insulating layer 420 (see FIG. 18), and a fourth opening pattern 442 corresponding to the second region may be formed in the first mask pattern 440 (see FIG. 18) (S330).

Referring to FIG. 19, a pattern corresponding to the first region 484 (see FIG. 17) and exposing the etch stop layer may be formed and the third opening pattern 444 exposing the upper surfaces of the gate pattern 404 and the source and drain 402 may be formed. Further, the fourth opening pattern 442 corresponding to the second region 482 (see FIG. 17) may be formed in-situ. In other implementations, other suitable methods for forming the third opening pattern 444 and the fourth opening pattern 442 may be used. The opening patterns formed on the rear side of the third opening pattern 444 of FIG. 19 correspond to the first opening pattern formed in S310 and the fourth opening pattern 442 formed in S330. The fourth opening pattern 442 and the first opening pattern 440 included in the first mask pattern correspond to a portion where the interlayer metal wiring is formed. The third opening pattern 444 corresponds to a contact hole connecting the interlayer metal wiring with the source, drain or gate pattern.

The semiconductor device may be fabricated by depositing metal on the portions corresponding to the interlayer metal wiring and the contact hole.

The method for forming the third opening pattern 444 and the fourth opening pattern 442 in-situ may be similar to what has been described with reference to FIGS. 8 to 10 and 14. Accordingly, a description thereof will not be repeated.

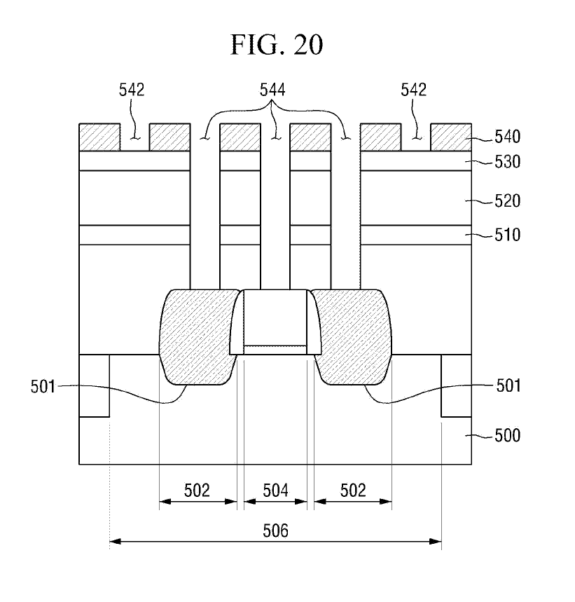

FIG. 20 is a diagram for explaining a method for fabricating a semiconductor device in accordance with still another embodiment. Herein, differences from the method for fabricating a semiconductor device in accordance with the embodiment illustrated in FIGS. 16 to 19 will be described.

An active region 506 may be defined on a substrate 500. A gate pattern 504 may be formed in the active region 506, and a source and drain 502 may be formed on both sides of the gate pattern to protrude from the substrate. A suitable method may be used in forming the gate pattern 504 and the protruding source and drain 502. A transistor may be formed in the active region 506 (see FIG. 20). In other implementations, other suitable structures, such as a diode, may be formed therein.

Trenches 501 may be formed by etching both sides of the gate pattern 504 on the substrate 500, and the source and drain 502 may be formed by filling up the trenches 501. The source and drain 502 formed by filling up the trenches 501 may protrude (i.e., may be elevated) from the substrate 500. The protruding source and drain 502 may be formed by epitaxial growth.

In the case of a PMOS semiconductor device, the source and drain 502 may be formed by epitaxially growing a material having a larger lattice constant than a material of the substrate, e.g., silicon germanium (SiGe), when the substrate is formed of silicon. In the case of an NMOS semiconductor device, the source and drain 502 may be formed by epitaxially growing a material having a smaller lattice constant than a material of the substrate, e.g., silicon carbide (SiC), when the substrate is formed of silicon.

Subsequently, the semiconductor device may be fabricated by the method described with reference to FIGS. 16 to 19.

By way of summation and review, with the development of electronic technology, down-scaling of semiconductor devices has been rapidly progressing. In order to form a contact hole or via between interlayer metal lines in a down-scaled semiconductor device without failure, various studies using lithography and etching processes are being conducted. As one of the methods for forming a pitch of 60 nm or less, there is a litho-etch-litho-etch (LELE) method.

Embodiments disclosed herein may advance the art by providing a method for forming a pattern, such as a pattern to form a contact hole or via, through in-situ etching without additional photolithography and etching, and by providing a method for fabricating a semiconductor device using the method for forming a pattern.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope as set forth in the following claims.

What is claimed is:

1. A method for forming a pattern, the method comprising:
forming a first layer on an underlying layer on a substrate;
forming a first mask pattern including a first opening pattern on the first layer;
forming a second mask pattern including a second opening pattern on the first mask pattern, the second opening pattern including a first region overlapping the first opening pattern and a second region not overlapping the first opening pattern, and
performing etching using the second mask pattern such that a third opening pattern corresponding to the first region and exposing an upper surface of the underlying layer is formed in the first layer, and a fourth opening pattern corresponding to the second region is formed in the first mask pattern.

2. The method as claimed in claim 1, wherein the third opening pattern and the fourth opening pattern are formed by an in-situ etching process.

3. The method as claimed in claim 1, wherein the third opening pattern and the fourth opening pattern are formed simultaneously.

4. The method as claimed in claim 1, further comprising forming a planarization layer after forming the first mask pattern and before forming the second mask pattern.

5. The method as claimed in claim 4, wherein the planarization layer includes a spin-on hardmask (SOH).

6. The method as claimed in claim 1, wherein the first mask pattern is formed of a material having higher etching selectivity than that of the first layer.

7. The method as claimed in claim 6, wherein the first mask pattern includes titanium nitride (TiN).

8. A method for fabricating a semiconductor device, the method comprising:
sequentially forming a first metal wiring and an insulating layer on a substrate;
forming a first mask pattern including a first opening pattern on the first insulating layer;
forming a second mask pattern including a second opening pattern on the first mask pattern, the second opening pattern including a first region overlapping the first opening pattern and a second region not overlapping the first opening pattern; and
performing etching using the second mask pattern such that a third opening pattern corresponding to the first region and exposing an upper surface of the first metal wiring is formed in the first insulating layer, and a fourth opening pattern corresponding to the second region is formed in the first mask pattern.

9. The method as claimed in claim 8, wherein the third opening pattern and the fourth opening pattern are formed by an in-situ etching process.

10. The method as claimed in claim 8, wherein the third opening pattern and the fourth opening pattern are formed simultaneously.

11. The method as claimed in claim 8, further comprising forming a planarization layer after forming the first mask pattern and before forming the second mask pattern.

12. The method as claimed in claim 11, wherein the planarization layer includes a spin-on hardmask (SOH).

13. The method as claimed in claim 8, wherein the first mask pattern is formed of a material having higher etching selectivity than the first insulating layer.

14. The method as claimed in claim 13, wherein the first mask pattern includes titanium nitride (TiN).

15. The method as claimed in claim 8, wherein the first insulating layer includes a low dielectric constant material.

16. A method of forming a patterned structure, the method comprising:
sequentially forming a metal wiring, an etch-stop layer, and an insulating layer on a substrate;
forming a first mask pattern on the insulating layer, the first mask pattern including a first opening pattern;
forming a planarization layer on the first mask pattern;
forming a second mask pattern including a second opening pattern on the planarization layer, the second opening pattern including a first region overlapping the first opening pattern and the metal wiring and a second region not overlapping the first opening pattern, and
performing etching using the second mask pattern to form the patterned structure, the patterned structure including a contact hole corresponding to the first region and extending to expose the metal wiring, and a trench corresponding to the second region in the first mask pattern.

17. The method as claimed in claim 16, wherein:
the insulating layer includes a low dielectric constant material;
the first mask pattern includes titanium nitride (TiN); and
the planarization layer includes a spin-on hardmask (SOH).

18. The method as claimed in claim 17, wherein the performing of the etching using the second mask pattern is carried out by an in-situ etching process.

19. The method as claimed in claim 18, further including filling the contact hole and the trench with a conductive metal.
